(19) United States
(12) Patent Application Publication
(10) Pub. No.: US 2011/0068268 A1
(43) Pub. Date: Mar. 24, 2011

(54) TERAHERTZ IMAGING METHODS AND APPARATUS USING COMPRESSED SENSING

(75) Inventor: Abdorreza Heidari, Waterloo (CA)

(73) Assignee: T-RAY SCIENCE INC., Waterloo (CA)

(21) Appl. No.: 12/884,492

(22) Filed: Sep. 17, 2010

Related U.S. Application Data
(60) Provisional application No. 61/243,559, filed on Sep. 18, 2009.

(51) Int. Cl. H01L 31/00

(52) U.S. Cl. 250/330

(57) ABSTRACT

A system, method and an apparatus for terahertz (THz) imaging based on compressed sensing using a unified sensing mask are provided herein. The system may include a THz radiation transmitter, a window, a unified mask, a THz radiation focusing lens, a THz radiation detector and a processor to generate an image using compressed sensing. The unified mask includes a series of individual masks for filtering radiation directed at the individual masks. Each of the individual masks defines a binary two-dimensional matrix of cells that are either a radiation blocking cell or a radiation passing cell. The unified mask has a first length in a first direction. The window has a terahertz radiation blocking border that defines a terahertz radiation passing opening. The opening has a second length aligned in the first direction and the second length is less than the first length so that the unified mask is movable relative to the window to a plurality of different positions and the opening operates to select one of the individual masks at each of the positions.

### RELATED APPLICATION

This application claims priority from U.S. provisional patent application Ser. No. 61/243,559 entitled Unified Sensing Matrix for a Single-Pixel Detector Based on Compressive Sensing filed Sep. 18, 2009.

### FIELD

The present invention relates to imaging systems, in particular, to imaging systems based on compressed sensing.

### BACKGROUND

Single-pixel terahertz detectors allow for high quality images to be captured. However, conventional single-pixel detectors require a raster scanning technique. Raster scanning involves moving the target object relative to the terahertz beam and the single-pixel detector in order to take a measurement for each pixel of the desired image. For example, to capture an N×N pixel image using a raster scanning technique requires N² measurements with a mechanical translation of the object or source-sensor pair between each measurement. This mechanical scanning motion limits the image acquisition speed and requires static targets. Although detector arrays may be used for faster imaging, these array detectors are not mature enough and require higher power sources as the power of the terahertz radiation is divided among the cells. Other approaches that use electro-optic sensing or unconventional source arrays also tend to be more complex systems with higher operational costs.

Compressed sensing (also called compressive sampling, compressed sampling, or sparse sampling) is an approach that has been applied to many fields recently, such as imaging and sensing; data acquisition; and compression and coding, among others. Imaging applications include MRI, low-light and sensitive cameras, and single-pixel cameras. The compressed sensing technique exploits the concept that most signals contain some structure or redundancy, and thus are considered compressible. Rather than scan every single pixel like a raster scan, compressed sensing approaches exploit the signal compressibility to under sample the signal space. By measuring fewer samples, compressed sensing approaches should, in theory, provide a faster approach than conventional methods (including raster scanning) without sacrificing any noticeable quality.

Traditionally a signal is acquired and then compressed through some known compression routine. For example, a consumer camera device that captures an image with a 400×600 VGA CCD or CMOS sensor array could use JPEG compression on the acquired 240,000 pixels (400×600) to reduce the size of the stored image. A compressed sensing approach, exploiting that the image is compressible, is able to acquire less data to reconstruct the signal. Using the previous example, the compressed sensing approach could use a single-pixel camera to acquire much less than 240,000 measurements yet still reconstruct the image almost perfectly using the mathematical optimizations of compressed sensing.

Shown in FIG. 1 is the Rice Single-Pixel Camera Project, an example of a single-pixel camera system that uses compressive sampling. The single-pixel camera system 100 uses a single-pixel detector 110 to capture the target object 120 by capturing the light transmitted through lenses 130 and 140 and reflected from the digital micromirror device (DMD) 150. The advantage of single-pixel detectors is that they can be designed to be very sensitive or sensitive to a specific portion of the electromagnetic spectrum, such as infrared, that may not be possible in other sensor arrays. The DMD 150 contains an array of microscopic mirrors that implement optical masks by either reflecting light towards or away from the single-pixel detector. Each micromirror represents a single pixel in the optical mask and desired image. The optical masks are a random binary matrix provided by random number generators 160 that drive each row of the DMD 150. For each random optical mask generated by the DMD 150, the analog/digital converter 170 captures the data from the detector 110 and transmits the data to the digital signal processor (DSP) 180. If the DMD 150 mirror array is an N×N array, using compressed sensing reconstructions, the DSP 180 should require much less than N² data points to reproduce an N×N pixel image of the target object 120.

Terahertz radiation is between the microwave and infrared regions of the electromagnetic spectrum. This creates practical difficulties, as it is too high a frequency to be manipulated electrically like microwaves and too low a frequency to be controlled by optical means. Consequently, the DMD approach used in the Rice Single-Pixel Camera, using DMD's available on the market, will not work with terahertz radiation and other non-optical radiation sources. Active metamaterial structures are currently too expensive and do not provide sufficient efficiency over the terahertz bandwidth to be practical for use as a terahertz mask.

Chan et al., “A single-pixel terahertz imaging system based on compressed sensing”, Applied Physics Letters, vol. 93, p. 121105, 2008, proposed a set of terahertz masks for compressed sensing using a set of six hundred random patterns printed in copper on a standard printed circuit board (PCB). Each mask was 32×32 pixels with the copper material blocking the terahertz radiation and the PCB material passing the terahertz radiation. For each random pattern, a single measurement was taken consisting of the superposition of the radiation transmitted through the non-copper pixels. These measurements were then used in a compressed sensing reconstruction to recover a 32×32 pixel image of the target object.

The approach of Chan et al. is limited to the speed of the translation between masks similar to how raster scanning methods are limited to the speed of the mechanical scanning motion. While Chan et al. provide a proof of concept for a terahertz single-pixel imaging systems, the approach does not provide any significant improvement of the data acquisition speed over raster scanning approaches. Alignment errors between the patterns may also introduce noise that further affects the quality of the reconstructed image.

Single-pixel camera systems can provide improved sensitivity by using a single-point detector. However, the acquisition speed of these systems is limited by mechanical translation, such as in raster scanning or translating masks in compressed sensing approaches. In principle, compressed sensing approaches should provide a faster acquisition process by requiring fewer samples than raster scanning approaches. Improvements may be made to compressed sensing approaches that reduce the translation delay and simplify the implementation of the sensing masks.

### SUMMARY

According to one aspect of the invention, there is provided a terahertz imaging system comprising a terahertz radiation transmitter that generates at least one terahertz beam directed at a target object, a window having a terahertz radiation blocking border that defines a terahertz radiation passing opening positioned in the path of the beam directed at the target object, and a unified mask comprising a series of individual masks for filtering terahertz radiation directed thereto. Each of the individual masks defines a binary two-dimensional matrix of cells and each of the cells either is a terahertz radiation blocking cell or a terahertz radiation passing cell. The unified mask has a first length in a first direction and the opening of the window has a second length aligned in the first direction. The second length is less than the first length so that the unified mask is movable relative to the window to a plurality of different positions and the opening operates to select one of the individual masks at each of the positions. The system further comprises a terahertz radiation focusing lens for converging the terahertz beam filtered by the target object and at least some of the selected individual masks into an area that is smaller than an area of one of the individual masks to produce converged terahertz beams associated with the selected individual masks, a terahertz radiation detector operable to receive the converged terahertz beams and generate measurement values, each of the measurement values being indicative of an aggregate of each converged terahertz beam, and at least one processor programmed to generate an image associated with the target object using compressed sensing based on the measurement values and configurations of the radiation blocking cells and radiation passing cells on each selected individual mask.

In accordance with another aspect of the invention, there is provided a terahertz imaging method comprising the steps of generating at least one terahertz radiation beam directed at a target object and providing a unified mask comprising a series of individual masks for filtering terahertz radiation directed thereto. Each of the individual masks defines a binary two-dimensional matrix of cells, each of the cells being a terahertz radiation blocking cell or a terahertz radiation passing cell, and the unified mask has a first length in a first direction. The method further comprises the step of selecting an individual mask using a window having a terahertz radiation blocking border that defines a terahertz radiation passing opening positioned in a path of the at least one terahertz beam directed at the target object. The opening has a second length aligned in the first direction and the second length is less than the first length so that the unified mask is movable relative to the window to a plurality of different positions and the opening operates to select one of the individual masks at each of the positions. The method further comprises the steps of filtering the at least one terahertz beam through the selected individual mask and the target object to generate a filtered terahertz beam, converging the filtered terahertz beam into an area that is smaller than the area of the selected individual mask to produce a converged terahertz beam, receiving the converged terahertz beam to generate a measurement value indicative of an aggregate of the converged terahertz beam and determining whether a selected number of measurement values has been generated. If it is determined that the selected number of measurement values has not been generated, the proceeds to the step of selecting another individual mask by moving the unified mask to another position such that the window selects a different individual mask and repeating some of the steps described above to generate a measurement value for that individual mask. If it is determined that a selected number of measurement values has been generated, the method proceeds to the step of processing the measurement values and configurations of the radiation blocking cells and radiation passing cells on each selected individual mask based on compressed sensing using a processor to generate an image associated with the target object.

In accordance with yet another aspect of the invention, there is provided a sensing apparatus for use in a terahertz imaging system using compressed sensing comprising a window having a terahertz radiation blocking border that defines a terahertz radiation passing opening positioned in the path of the beam directed at the target object, and a unified mask comprising a series of individual masks for filtering terahertz radiation directed thereto. Each of the individual masks defines a binary two-dimensional matrix of cells and each of the cells either is a terahertz radiation blocking cell or a terahertz radiation passing cell. The unified mask has a first length in a first direction and the opening of the window has a second length aligned in the first direction. The second length is less than the first length so that the unified mask is movable relative to the window to a plurality of different positions and the opening operates to select one of the individual masks at each of the positions.

In accordance with yet another aspect of the invention, there is provided a unified sensing mask for use with a compressed sensing imaging system comprising a series of individual masks for filtering radiation directed thereto, each of the individual masks defining a binary two-dimensional matrix of cells, each of the cells being a radiation blocking cell or a radiation passing cell. The unified sensing mask is movable relative to a radiation transmitter to a plurality of different positions to select one of the individual masks for filtering radiation generated by the radiation transmitter at each of the positions.

### BRIEF DESCRIPTION OF THE DRAWINGS

FIG. 1 is a schematic perspective view of a single-pixel camera that uses compressive sampling;

FIG. 2 is a schematic diagram of a single-detector terahertz imaging system based on compressed sensing, having a unified sensing mask made in accordance with an exemplary embodiment of the invention;

FIG. 3A is a side elevational view of an embodiment of a unified sensing mask having overlapping consecutive masks;

FIG. 3B is a magnified view of a portion of the unified sensing mask of FIG. 3A, showing two overlapping masks;

FIG. 4 is a side elevational view of an embodiment of a unified sensing mask having overlapping consecutive masks mapped to a circular axis on a chopper blade;

FIG. 5A-5D are images of sample recovery results using a unified sensing mask and compressed sensing reconstruction in accordance with the present invention; and

FIG. 6 is a block diagram of a terahertz imaging method according to another embodiment of the invention.

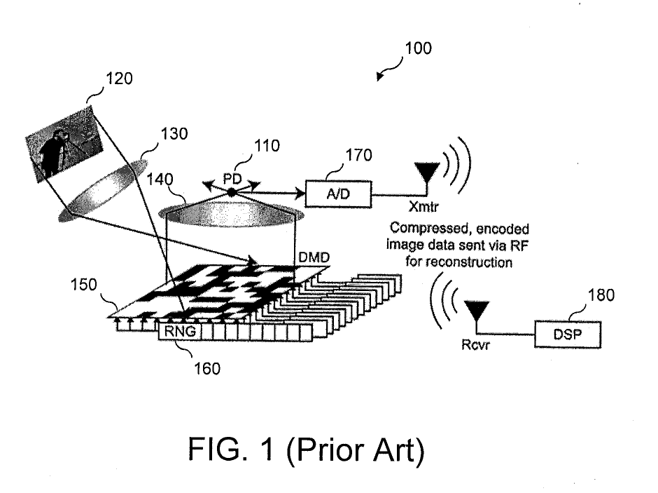

### DESCRIPTION OF VARIOUS EMBODIMENTS

Compressed sensing imaging systems are based on the following general linear sensing model:

y=Ax+z

where y is an M×1 column vector of measurements, x is the desired image vector having N pixels ordered in an N×1 vector, A is an M×N sensing matrix, and z is a noise vector. Compressed sensing approaches acquire a much smaller number of measurements than the number of pixels in the desired image, that is M<<N. It would seem that the system of equations is mathematically insolvable by standard ideas of linear algebra as the system of linear equations is underdetermined and cannot have a unique solution. However, compressed sensing relies on the property that x is compressible to a nearly sparse vector through the operation of a compression algorithms.

When A is a random binary matrix, the compressed sensing approach may be used to recover the image with a high probability. The entries of the binary matrix may be chosen from random distribution of 1's and 0's with equal probability so that for any row of the sensing matrix A, approximately half of the entries are set to 1 and the remainder to 0. This is one known method to produce a random and independent mask for each measurement. However, implementing an independent random mask and applying it for each measurement creates difficulties and high degrees of complexity in systems where each mask must be mechanically built and translated. Other approaches that use independent binary masks may also have more complicated hardware to implement the masks.

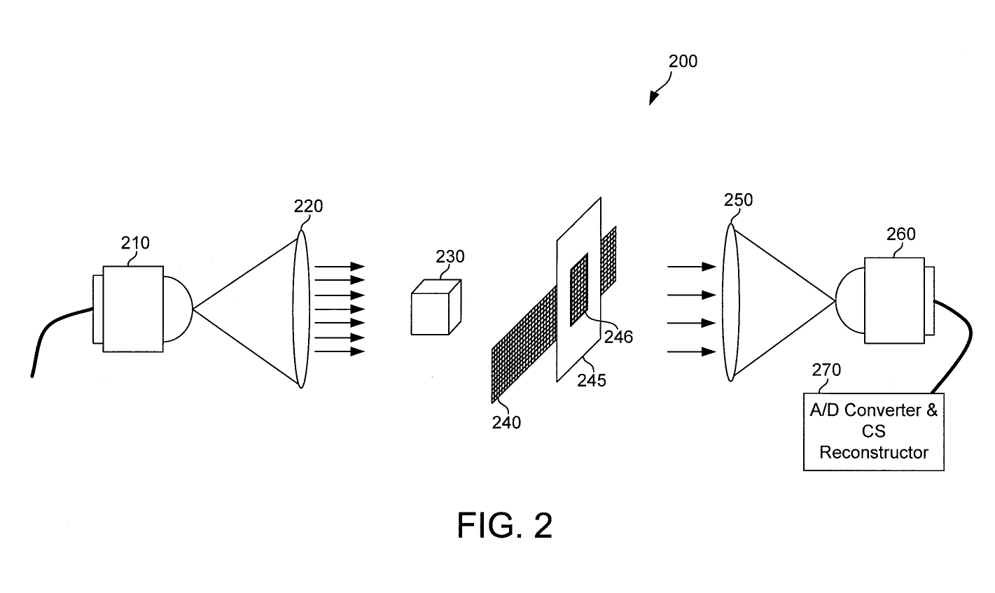

FIG. 2 shows an embodiment of a single-detector terahertz imaging system 200 based on compressed sensing, made in accordance with an embodiment of the present invention. The terahertz transmitter 210 generates a terahertz beam directed towards lens 220. The lens 220 collimates the terahertz beam so as to provide a uniform beam of terahertz radiation over the surface area of the subject to be imaged or target object 230. The terahertz transmitter 210 may be a photoconductive antenna or any other known terahertz source, including continuous wave and pulse sources. An array of terahertz transmitters may also be used to simulate a beam with a larger cross-sectional surface area. If the terahertz beam is determined to have a sufficiently large cross-sectional surface area with an evenly distributed radiation field, the lens 220 may be omitted or replaced with other optical components. The radiation beam strikes the surface area of the target object 230 and the energy of the beam will be attenuated according to the subject matter of the target object 230. For example, metallic surfaces or water will act to attenuate the terahertz beam power more relative to cloth or glass. The subject matter and depth of the target object 230 may also introduce a measurable phase change that can be used to reconstruct an image of the target object 230.

After passing through the target object 230, the attenuated terahertz beam is then directed at a portion of the unified sensing mask 240. In some embodiments, the portion of the unified sensing mask 240 may be an individual mask. The unified sensing mask 240 contains a random binary pattern of cells that block or pass terahertz radiation. Some embodiments of the system may also include a window 245 having a radiation-blocking border that defines an opening 246 that allows the radiation to pass through to the terahertz detector 260. The window 245 may be placed anywhere between the lens 220 and lens 250. The opening 246 acts to select a single random binary individual mask upon the unified sensing mask 240.

In some embodiments, the unified sensing mask 240 may be implemented using a metal deposition for blocking terahertz radiation on a material that appears transparent to the terahertz radiation (e.g. a copper mask printed on a printed circuit board). A person skilled in that art may construct the unified sensing mask using any material that blocks or sufficiently attenuates the terahertz beam, either with or without a substrate. The term ‘block’ is used throughout to mean that the radiation is sufficiently attenuated for any practical mask implementations.

After passing through the unified sensing mask 240 and opening 246, the terahertz beam is focused using lens 250 on the terahertz detector 260. The terahertz detector 260 translates the energy of the received terahertz radiation to an electrical signal that may be processed by receiver hardware 270. In a preferred embodiment, the terahertz detector 260 is a photoconductive antenna that is gated using an optically delayed terahertz beam (not shown for simplicity) generated by using a pulsed terahertz source for transmitter 210. The photoconductive antenna is more sensitive and practical than other currently known terahertz detectors. However, other embodiments may use other detection methods, including detector arrays. If a detector array is used, lens 250 may be omitted or replaced with other optical components and the power received over the entire array should be used in the compressed sensing reconstruction. In some embodiments, the use of lenses and mirrors may be combined in a single system.

The above embodiments may be referred to as a transmission mode imaging system since the system measures radiation transmitted through target object 230. Other embodiments of system may use reflection mode imaging to measure the radiation reflected by the target object. In a reflection mode system, the reflected radiation beam passes through the components of the system to the radiation detector.

To implement a compressed sensing imaging system, a number of random, independent masks are required for each measurement. The window 245 selects a single random binary individual mask on the unified sensing mask 240. After taking a measurement with this individual mask, the unified sensing mask 240 is moved relative to the window 246 so that the window 245 selects another individual mark comprising a random binary sensing matrix along the length of the unified sensing mask 240. The unified sensing mask 240 may be so that successive individual masks overlap. The unified sensing mask 240 may be attached to a mechanical translation (not shown) powered by a motor that is in communication with the system 200 electronics to facilitate shifting the unified sensing mask in between measurements.

The shift and measure approach may be used to generate M random binary individual masks. For example, if the window 246 defined a 9×9 pixel mask, the unified sensing mask 240 may be shifted to create M random binary individual masks. The set of M individual masks may be used for reconstructing an 81-pixel image with compressed sensing. The set of individual masks may be designed with variable dimensions and pixel sizes to achieve the desired size and image resolution. Whereas a raster scanning approach would require 81 separate measurements, the compressed sensing system 200 may use M measurements where M is much less than 81. The receiver hardware 270 quantifies each measurement through analog to digital conversion. After a sufficient number of measurements are received, the receiver hardware 270 may reconstruct an image of the target object 230 using a compressed sensing approach.

According to the above linear sensing model, the set of M random individual masks is collectively formulated in the sensing matrix A, where each row in A represents a vectorized individual mask. Each of the received measurements collectively forms the measurement vector y. Since x is compressible by a compression operation D[x] that signifies the sparsity of the image, in some embodiments the image may be recovered by solving the following convex minimization problem:

$${min}_{x ∈ {ℜ}^{N}} {‖ D [ x ] ‖}_{𝓁1} subject to {‖ Ax - y ‖}_{𝓁 2} \leq ɛ$$

where ∥ ∥ₗ₁ and ∥ ∥ₗ₂ denotes the standard l₁ norm (sum of absolute values) and l₂ norm (square root of the sum of squared absolute values) respectively. The amount of noise in the result may be controlled by selecting E in accordance with the anticipated size of the absolute noise z. An estimate of z may be obtained through calibrating the imaging system 200. The D[x] operator should be selected such that it can adequately signify the sparsity of the image. This may include a transform such as a discrete wavelet transform, a discrete Fourier transforms, a discrete curvelet transform, discrete ridgelet transform, or other known sparse mathematical transforms. Other embodiments may apply alternative approaches that rely on solving alternative convex minimization problems or that apply iterative regression approaches, such as matching pursuit or iterative hard thresholding.

The receiver hardware 270 may be comprised of an application specific integrated circuit (ASIC) or field programmable gate array (FPGA) having registers or memory for matrices and vectors. The ASIC or FPGA may also implement a specialized vector math unit to allow for faster processing. Other embodiments of the receiver hardware 270 may comprise a digital signal processor, a microprocessor system, or any computer hardware capable of implementing compressive reconstruction software. The microprocessor or other hardware may be programmed to implement a specific compressed sensing reconstruction approach. Highly parallel microprocessors, such as IBM's Cell processor, may provide improved performance relative to microprocessors with less parallelism. The microprocessor system may also be combined with one or more graphical processing units (GPU) that are commonly used for rendering 3D graphics for personal computers. The microprocessor and GPU may be discrete parts or combined in a single package. A GPU contains a number of parallel processors that are optimized for vector operations thereby accelerating most reconstruction algorithms. The microprocessor and/or GPU receiver hardware may be implemented as a custom designed circuit board or as a special purpose personal computer in combination with compressive reconstruction software.

The single-detector imaging system may also be used as a shutterless video camera. By selecting an operator D[x] that not only exploits the spatial redundancy of each measurement vector y but also exploits the temporal redundancy between successive measurements. This effectively adds a third dimension (i.e. time) to the linear sensing model y=Ax+z.

While the embodiment shown in FIG. 2 is directed at terahertz radiation, the system may be implemented in a similar fashion for other electromagnetic radiation. Other embodiments of the system may rely on the same principles of operation of the above described system with respect to radio waves, microwaves, infrared, visible light, or X-rays. Applications in these spectra may include MRI, X-ray imaging and tomography, and low-light or infrared cameras. The term radiation is used throughout the application to refer to the full spectrum of practicable electromagnetic radiation. The compressed sensing approach utilizing multiple physical individual masks is particularly useful for electromagnetic radiation that cannot be modulated by other means such as X-Ray. A unified sensing mask comprised of a dense material, such as lead, deposited on a low-density substrate could be used for X-Ray applications.

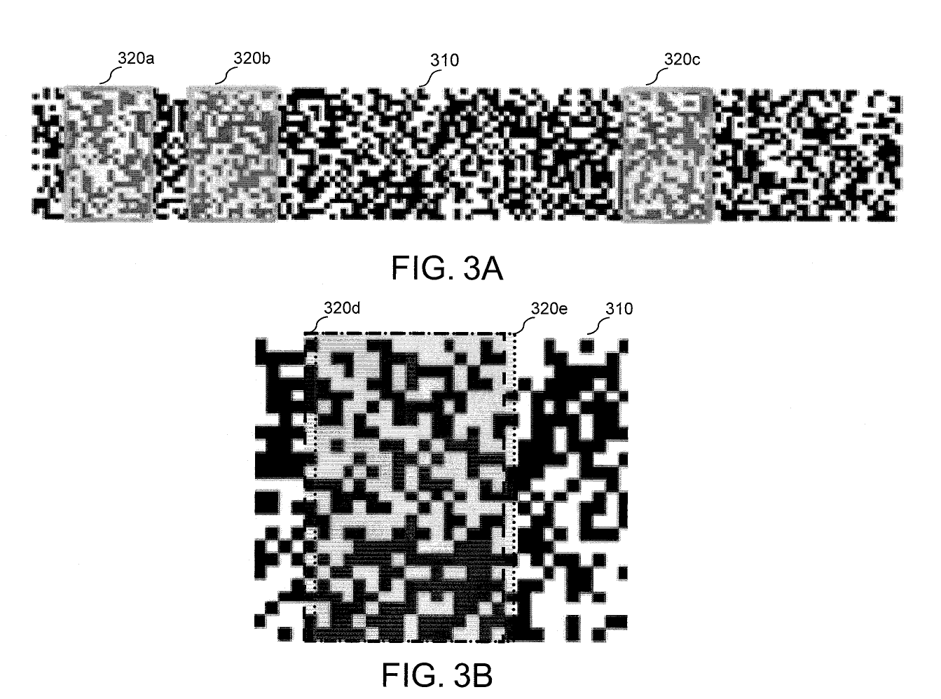

FIG. 3A shows an embodiment of a unified sensing mask 310 with consecutive individual masks overlapping, made in accordance with the present invention. The dark and white areas of unified sensing mask 310 are used to represent the radiation blocking cells and the radiation passing cells of the unified sensing mask 310 respectively. In a preferred embodiment, the entries of the unified mask 310 should be chosen from a random distribution of 1's and 0's with equal probability so that each of the consecutive individual masks is likely to have the same property. By shifting a window over the unified mask 310, the set of masks obtained have the desired properties intended for the binary masks.

In FIG. 3A, three separate individual masks are shown by three windows 320a-c that are overlaid on the unified sensing mask 310. FIG. 3B shows a magnified view of the unified sensing mask of FIG. 3A where two separate individual masks overlap, separated by a single-bit width column. A dashed line defines the left-most window 320d. Window 320e is defined by a dotted line and is shifted over by a single-bit width column to the right of window 320d. The term column is used throughout the application to not only refer to the vertical set of binary elements along the length of the unified mask but also more generally to refer to the line of binary elements that are perpendicular to the direction of translation of the unified mask.

The dimension of windows 320a-e (and the corresponding individual masks) corresponds to physical capture size and image resolution. For example, if the window dimensions are 2 inches by 3 inches, then only a 2 inch by 3 inch projection of the target object may be captured. The number of bits in the window determines the number of pixels of the image. The windows 320d and 320e shown in FIG. 3B are 16 bits wide by 24 bits tall resulting in a 384-pixel image. Using the dimensions and pixel count the resolution may be calculated in pixels per unit area.

By overlapping consecutive individual masks, the entire set of individual masks is much more compact. If the window, image and individual mask dimension is Nₓ pixels by N_{y} pixels, and M measurements are needed, the conventional method would require a combined individual mask size of M Nₓ N_{y} pixels. For example, the approach of Chan et al. required a combined individual mask size of 614,400 pixels (32×32 image over 600 measurements). Using a unified mask with consecutive overlapping individual masks only requires (M+Nₓ−1) N_{y} pixels. Implementing the image size and measurements from Chan et al. using a unified mask would only require 20,192 pixels ((600+32−1) 32), approximately 3% of the combined Chan et al. mask size. In an embodiment with a desired 42×48 image size (2016 pixel image) that may be reconstructed with 1,000 measurements, the physical dimensions of the entire unified mask would only be 521 mm×24 mm for a 0.5 mm square pixel.

Returning to the linear sensing model, the effect of shifting the window by a single column of pixels means that each row of the sensing matrix A is a shifted version of the previous row with some new random binary elements. The resulting sensing matrix A has a Toeplitz construction, meaning all of the descending diagonals from left to right are a constant. Toeplitz structured matrices with entries drawn independently from a probability distribution are independent and identically distributed compressed sensing matrices. A Toeplitz structured sensing matrix performs almost the same as the case with a random binary sensing matrix.

In some embodiments, the unified sensing mask 310 may be implemented by using radiation-blocking material to provide the mask pattern. In a compressed sensing application with a single terahertz detector such as that shown in FIG. 2, the unified mask may be implemented using copper deposited onto a PCB. The PCB may be placed after the target object on a translation stage powered by a motor that can shift the PCB by the distance of single pixel after each measurement or with a desired speed. Translating a lightweight PCB in one dimension may be accomplished more efficiently and faster than raster scanning approaches that may be moving a potentially heavy target object or translating the transmitter-receiver pair in two dimensions.

By defining an opening in a radiation-blocking border, placed either before or after the unified sensing mask, the accuracy of approach may be improved. The radiation passing through the opening acts to select an individual mask having the same dimensions as the opening on the unified sensing matrix. The border prevents radiation that passes through adjacent masks from altering the power received by the detector thereby eliminating noise and increasing the accuracy of the image reconstruction. In the terahertz example, a radiation-blocking metal border with an Nₓ pixel by N_{y} pixel opening may be placed in front of the unified sensing mask PCB so that the aperture is in fixed alignment with the radiation beam incident on the detector. The window now only allows an Nₓ pixel by N_{y} pixel portion of the unified mask to be irradiated by the terahertz beam.

Using a window approach allows more flexibility in designing the unified mask and selecting the desired image size. For example, if the unified mask has sufficient dimensions, the system could implement a number of image sizes by changing the opening size in the window or having a number of interchangeable windows with different opening sizes. Of course, larger image sizes require more measurements, so the number of consecutive individual masks contained in the unified mask is the limiting factor. Since the size of the bits on the unified sensing mask is constant, windows with openings larger than a threshold size may have poorer resolution (pixels/unit area).

The dimensions of the unified mask may also be designed to allow consecutive individual masks to be generated by translating the unified mask in either a horizontal or vertical direction. The PCB translation pattern could use a left-right single pixel translation until the edge of the unified mask is reached followed by a single pixel upward translation and repeating these steps until the bottom of the PCB is reached or the desired number of measurements have been acquired. This results in unified masks that are not as long and thus more compact.

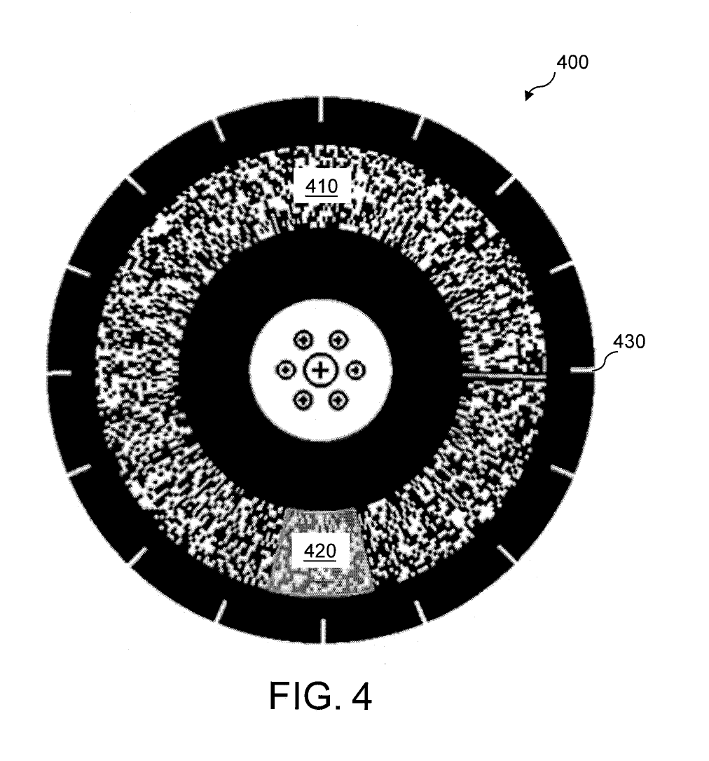

FIG. 4 shows an embodiment of a unified sensing mask having overlapping series of individual masks mapped to a circular axis. By providing the unified sensing mask in a circular axis allows the unified mask to be even more compact than the linear unified mask shown in FIG. 3. The circular mask can be obtained by a simple mapping of the Cartesian coordinates of the linear mask to polar coordinates. The blade 400 is used to support the circular unified sensing mask 410. The unified sensing mask 410 may be implemented using a radiation blocking material that is deposited on a radiation-passing blade 400. For example, the unified sensing mask 410 may be implemented by depositing metal on a glass blade 400. The circular unified sensing mask may also be implemented on a wafer substrate or using other materials. The blade 400 may also be designed similar to an optical chopper blade so that the blade 400 may be used with readily available hardware and systems developed for use with optical chopper blades. This includes mounting hardware, chopper motors and associated control systems. The blade 400 may also define one or more synchronization slots 430 that are commonly used with an infrared sensor and optical chopper blades control systems to synchronize the blade and monitor the angular velocity or position of the blade.

An individual mask is selected by opening of the window 420 that is overlaid on the unified sensing mask 410. The dimension of opening of the window 420 (and the corresponding masks) represents the image size. Due to the coordinate mapping to the circular axis, the shape of the opening of the window 420 is generally trapezoidal as shown. This also results in pixels closer to the central axis being smaller than those pixels farther from the central axis. However, this method does not introduce any skew or distortion to the image. Only the shape of the resulting image is not rectangular. The minimum resolution of the resulting image is related to the pixels farther from the central axis.

A minimum outer-radius for the blade may be calculated for a given M value, a minimum element size (or feature size), and a maximum image window skew. For example, an embodiment with Nₓ=28 and N_{y}=18 (a 504 pixel image is targeted), a radius of 42 mm (similar to a standard chopper blade), and a minimum element width of 0.44 mm, provides up to M=377 measurements. This number of measurements provides a sub-sampling ratio of about 0.75 (377:504), which is more than enough for typical images. The physical image size is roughly 19.4 mm×15.4 mm×12.3 mm×15.4 mm.

As described similarly above, a window having a border of radiation blocking material that defines an opening may be used to select a single mask from the unified sensing matrix 410. In the terahertz example, a window with an Nₓ pixel by N_{y} pixel opening may be placed in front or behind the blade 400 so that the opening is in fixed alignment with the terahertz detector and unified sensing mask 410. The radiation-blocking sheet now only allows an Nₓ pixel by N_{y} pixel portion 420 of the unified sensing mask to be irradiated at one time.

Any rotational stage (manual or motorized), or an electric chopper motor and controller may be used to rotate the blade 400 so that measurements can be quickly acquired for successive overlapping individual sensing masks as formed by the radiation passing through the window and the portion of the unified sensing mask. The chopper motor can continuously rotate the blade 400 at a speed or movement pattern that allows the terahertz detector to measure the power and set-up for the next measurement prior to the next individual mask being rotated in front of the detector. With respect to the limited duration of a terahertz pulse, the blade and mask will appear to be static. The pixel width, radius to the pixel, detector set-up and read time, and angular velocity of the pixel are all related to allow calculations to design a unified sensing mask on a circular axis and select an appropriate rate or pattern of rotation for the blade.

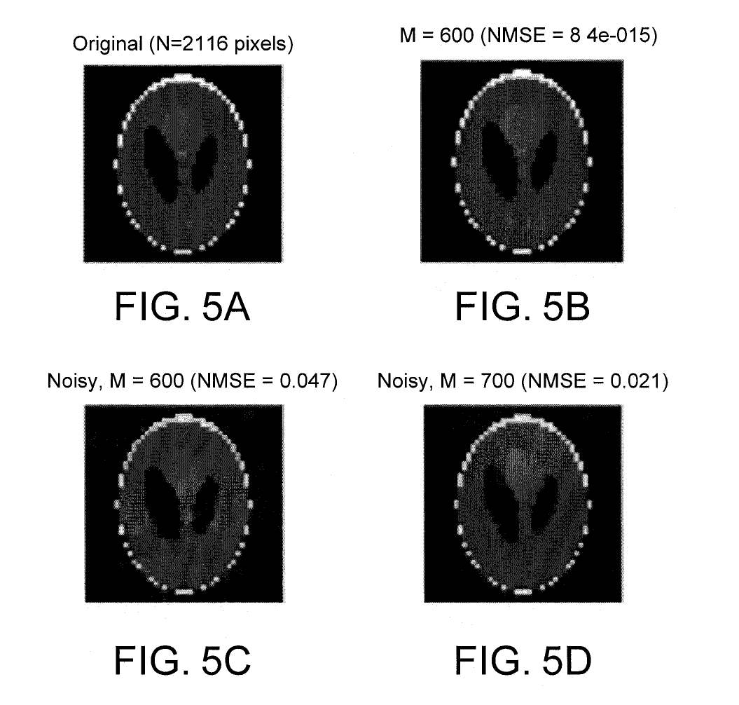

FIGS. 5A through 5D shows results from a sample recovery simulation using a unified sensing mask and a compressed sensing reconstruction. FIG. 5A shows the original 2,116-pixel image. FIGS. 5B-D show the results of a compressed sensing reconstruction using a Total Variation norm to signify the sparsity of the original image. A sub-sampling rate of around 30% is used to obtain the reconstructed images. A normalized mean squared error is used to determine the quality of the reconstructed image from the original image according to:

$$NMSE ≡ \frac{{‖ x - \hat{x} ‖}_{𝓁2}}{{‖ x ‖}_{𝓁2}}$$

FIG. 5B shows a near perfect recovery (NMSE=8.4e-15) for 600 measurements. FIGS. 5C and 5D include −20 dB noise with measurements and achieved a NMSE of 0.047 and 0.021 using 600 and 700 measurements respectively.

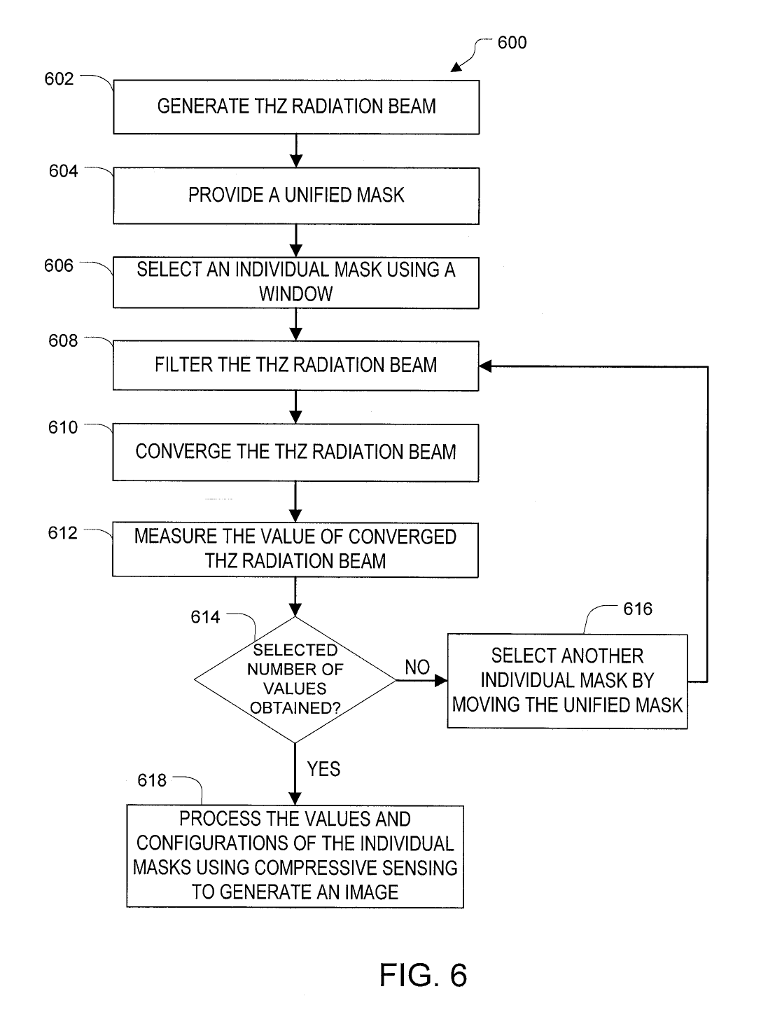

Referring now to FIG. 6, illustrated therein is a terahertz imaging method 600 according to another embodiment of the invention. The method 600 begins at step 602.

At step 602, at least one terahertz beam directed at a target object is generated. A terahertz transmitter such as a terahertz transmitter 210 shown in FIG. 2 and described above could be used to generate the terahertz beam in this step. In some embodiments, other suitable types of terahertz transmitter transmitters can be used. In some embodiments a focusing lens such as lens 220 may be used to collimate the terahertz so as to provide a uniform beam of terahertz over the surface area of the target object. In some embodiments, other types of lens or no lenses may be used.

At step 604, there is provided a unified mask comprising a series of individual masks for filtering terahertz radiation directed thereto. Each of the individual masks defines a binary two-dimensional matrix of cells and each of the cells is either a terahertz radiation blocking cell or a terahertz radiation passing cell. The unified mask having a first length in a first direction. For example, a unified mask such as the unified sensing mask 240, 340 or 410 shown and described above can be provided in step 604. In some embodiments, another type of unified mask different from the sensing masks 240, 340 or 410 may be provided in this step.

At step 606, a unique individual mask is selected using a window having a terahertz radiation blocking border that defines a terahertz radiation passing opening positioned in a path of the at least one terahertz beam directed at the target object. The opening of the window has a second length aligned in the first direction and the second length is less than the first length so that the unified mask is movable relative to the window to a plurality of different positions and the opening operates to select one of the individual masks at each of the positions. In some embodiments, the step 604 may use the window 245 or 420 as shown and described above to define an individual mask. In other embodiments, a window with an opening of a different shape and/or size may be used to define an individual mask.

At step 608, the at least one terahertz beam is filtered using the selected individual mask to generate a filtered terahertz beam.

At step 610, the filtered terahertz beam is converged into an area that is smaller than an area of the selected individual mask to produce a converged terahertz beam. In some embodiments, a focusing hardware such as a lens may be used to converge the filtered terahertz beam to a smaller area. In some embodiments, the lens may be the lens 250 as shown and described herein above. In some embodiments, the focusing hardware may be a lens that is different from lens 250. In some embodiments, the focusing hardware may not be a lens but a different type of focusing hardware.

At step 612, the converged terahertz beam is received by a terahertz detector which generates a measurement value for the converged terahertz beam. The measurement value is indicative of an aggregate of the terahertz beam filtered by the target object and selected segment of the unified mask. In some embodiments, a terahertz detector such as the terahertz detector 260 may be used to generate the measurement value. In some embodiments, another suitable terahertz detector may be used.

At step 614, it is determined whether a selected number of measurement values has been generated. In some embodiments, the selected number of the measurement values may be determined by the desired quality of the image and/or the compressed sensing algorithm described herein above. If the selected number of values has not been generated, the method 600 proceeds to step 616. Alternatively, if the selected number of values has been generated the method 600 proceeds to step 618.

At step 616, another individual mask is selected by moving the unified mask to another position such that the window selects a different individual mask. Depending on the shape of the unified mask being provided in step 604, the movement of the unified mask be translational, rotational or another type of movement. In some embodiments, the unified mask is moved by a single column of cells along the first direction. By moving the unified mask by a single column, the configuration of the radiation blocking cells and passing cells of the different individual mask selected by the window due to the movement is recordable as a Toeplitz matrix. In some embodiments, the unified mask may be moved in a direction other than the first direction. In other embodiments, the unified mask may be moved by multiple columns of cells or by another amount. Once another individual mask is selected, the method 600 repeats steps 608, 610, and 612 to generate a measurement value for that individual mask.

At step 618, the method 600 the measurement values and configurations of the radiation blocking cells and radiation passing cells of each selected individual mask based on compressed sensing using a processor to generate an image associated with the target object. In some embodiments, step 618 can use the compressed sensing formulae described above.

In some embodiments, some of the steps of the method 600 may be synchronized to other steps of the method such that multiple measurement values are generated automatically for the selected individual masks without need for an operator to move the unified mask.

The foregoing aspects of the system, apparatus and methods are provided for exemplary purposes only. Those skilled in the art will recognize that various changes may be made thereto without departing from the spirit and scope of the invention as defined by the appended claims.

1. A terahertz imaging system comprising:
a) a terahertz radiation transmitter for generating at least one terahertz beam directed at a target object;
b) a window having a terahertz radiation blocking border that defines a terahertz radiation passing opening positioned in the path of the beam directed at the target object;
c) a unified mask comprising a series of individual masks for filtering terahertz radiation directed thereto, each of the individual masks defining a binary two-dimensional matrix of cells, each of the cells being a terahertz radiation blocking cell or a terahertz radiation passing cell, the unified mask having a first length in a first direction;
d) wherein the opening of the window has a second length aligned in the first direction and being less than the first length so that the unified mask is movable relative to the window to a plurality of different positions, and the opening operates to select one of the individual masks at each of the positions;
e) a terahertz radiation focusing lens for converging the terahertz beam filtered by the target object and at least some of the selected individual masks into an area that is smaller than an area of one of the individual masks to produce converged terahertz beams associated with the selected individual masks;
f) a terahertz radiation detector operable to receive the converged terahertz beams and generate measurement values, each of the measurement values being indicative of an aggregate of each converged terahertz beam; and
g) at least one processor programmed to generate an image associated with the target object using compressed sensing based on the measurement values and configurations of the radiation blocking cells and radiation passing cells on each selected individual mask.

2. The terahertz imaging system according to claim 1, wherein the unified mask is movable between a first position that selects a first individual mask and a second position adjacent to the first position by moving the unified mask by a single column of cells along the first direction such that the window selects a second individual mask associated with the second position that overlaps the first individual mask except for the single column, the configuration of the radiation blocking cells and radiation passing cells of the second individual mask being recordable as a Toeplitz matrix.

3. The terahertz imaging system according to claim 1, wherein the individual masks are arranged in a linear series, the first direction is linear and the unified mask is translationally movable relative to the window along the first direction to select each individual mask.

4. The terahertz imaging system according to claim 1, wherein the individual masks are arranged in a curvilinear series, the first direction is curvilinear and the unified mask is rotatably movable relative to the window along the first direction to select each individual mask.

5. The terahertz imaging system according to claim 4, wherein the individual masks are arranged about a circular axis.

6. The terahertz imaging system according to claim 4, wherein each individual mask comprises radiation blocking material being deposited on a radiation passing chopper blade made of radiation passing material to form the radiation blocking cells and radiation passing cells.

7. The terahertz imaging system according to claim 1, wherein the unified mask comprises a terahertz radiation passing substrate and terahertz radiation blocking material is deposited on the radiation passing substrate to form the radiation blocking cells and radiation passing cells.

8. The terahertz imaging system according to claim 1, wherein or radiation blocking cells and radiation passing cells are at least one of randomly distributed and pseudorandomly distributed for each individual mask.

9. The unified sensing mask according to claim 1, wherein the radiation blocking cells and radiation passing cells are generally evenly distributed for each individual mask such that the measurement value that can be obtained for each individual mask is usable to generate the image using compressed sensing.

10. The terahertz imaging system according to claim 1, wherein the operation of the terahertz radiation transmitter and terahertz radiation detector is synchronized to the movement of the unified mask such that the measurement values are generated automatically for the selected individual masks.

11. The terahertz imaging system according to claim 1, wherein the terahertz radiation detector is a single-pixel detector.

12. A terahertz imaging method comprising the steps of:
a) generating at least one terahertz radiation beam directed at a target object;
b) providing a unified mask comprising a series of individual masks for filtering terahertz radiation directed thereto, each of the individual masks defining a binary two-dimensional matrix of cells, each of the cells being a terahertz radiation blocking cell or a terahertz radiation passing cell, the unified mask having a first length in a first direction;
c) selecting an individual mask using a window having a terahertz radiation blocking border that defines a terahertz radiation passing opening positioned in a path of the at least one terahertz beam directed at the target object, the opening having a second length aligned in the first direction and being less than the first length so that the unified mask is movable relative to the window to a plurality of different positions and the opening operates to select one of the individual masks at each of the positions;
d) filtering the at least one terahertz beam through the selected individual mask and the target object to generate a filtered terahertz beam;
e) converging the filtered terahertz beam into an area that is smaller than the area of the selected individual mask to produce a converged terahertz beam;
f) receiving the converged terahertz beam to generate a measurement value indicative of an aggregate of the converged terahertz beam;
g) determining whether a selected number of measurement values has been generated using a plurality of individual masks;
h) if it is determined that the selected number of measurement values has not been generated, selecting another individual mask by moving the unified mask to another position such that the window selects a different individual mask and repeating steps (d) to (g) to generate a measurement value for that individual mask; and
i) processing the measurement values and configurations of the radiation blocking cells and radiation passing cells on each selected individual mask based on compressed sensing using a processor to generate an image associated with the target object.

13. The terahertz imaging method according to claim 12, wherein the unified mask is moved by a single column of cells along the first direction such that the configuration of the radiation blocking cells and radiation passing cells of the different individual mask that is selected by the window is recordable as a Toeplitz matrix.

14. The terahertz imaging method according to claim 13, wherein the steps of generating the terahertz radiation beam and receiving the converged terahertz beam are synchronized to the step of moving the unified mask to select another individual mask such that the measurement values are generated automatically for the selected individual masks.

15. A sensing apparatus for use in a terahertz imaging system using compressed sensing comprising:
a) a window having a terahertz radiation blocking border that defines a terahertz radiation passing opening, the opening operable to be positioned in the path of a terahertz beam directed at a target object; and
b) a unified mask comprising a series of individual masks for filtering terahertz radiation directed thereto, each of the individual masks defining a binary two-dimensional matrix of cells, each of the cells being a terahertz radiation blocking cell or a terahertz radiation passing cell, the unified mask having a first length in a first direction;
c) wherein the opening of the window has a second length aligned in the first direction and being less than the first length so that the unified mask is movable relative to the window to a plurality of different positions and the opening operates to select one of the individual masks at each of the positions.

16. The unified sensing mask according to claim 15, wherein the unified mask is movable between a first position and a second position adjacent to the first position by moving the unified mask by a single column of cells along the first direction such that the window selects a second individual mask associated with the second position that overlaps a first individual mask associated with the first position, the configuration of the radiation blocking cells and radiation passing cells of the second individual mask being recordable as a Toeplitz matrix.

17. The unified sensing mask according to claim 15, wherein the individual masks are arranged in a linear series, the first direction being linear and the unified mask being translationally movable relative to the window along the first direction to select each individual mask.

18. The unified sensing mask according to claim 15, wherein the individual masks are arranged in a curvilinear series, the first direction being curvilinear and the unified mask being rotatably movable relative to the window along the first direction to select each individual mask.

19. The unified sensing mask according to claim 18, wherein the individual masks are arranged about a circular axis.

20. A unified sensing mask for use with a compressed sensing imaging system comprising a series of individual masks for filtering radiation directed thereto, each of the individual masks defining a binary two-dimensional matrix of cells, each of the cells being a radiation blocking cell or a radiation passing cell, the unified sensing mask being movable relative to a radiation transmitter to a plurality of different positions to select one of the individual masks for filtering radiation generated by the radiation transmitter at each of the positions.

21. The unified sensing mask of claim 20, wherein the radiation blocking cell comprises terahertz radiation blocking material and the radiation passing cell comprises terahertz radiation passing material such that the individual masks provided by the unified sensing mask are operable to filter terahertz radiation.
